(19) United States
(12) Patent Application Publication
(10) Pub. No.: US 2022/0359353 A1
(43) Pub. Date: Nov. 10, 2022

(54) PACKAGE WITH LASER LAPPED SURFACE AND METHOD OF MANUFACTURING SAME

(71) Applicant: Analog Devices International Unlimited Company, Limerick (IE)

(72) Inventors: Chee Leong Tham, Bayan Lepas (MY); Eng Tat Ng, Bayan Lepas (MY); Teik Tiong Toong, Tanjung Tokong (MY)

(21) Appl. No.: 17/737,831

(22) Filed: May 5, 2022

Related U.S. Application Data
(60) Provisional application No. 63/185,143, filed on May 6, 2021.

(51) Int. Cl. H01L 23/498; B23K 26/364; B23K 26/60; H01L 25/16; H01L 21/56; H01L 23/31

(52) U.S. Cl. CPC H01L 23/49816; B23K 26/364; B23K 26/60; H01L 25/165; H01L 21/565; H01L 23/49811; H01L 23/49838; H01L 23/3128; H01L 23/315; B23K 2101/40

(57) ABSTRACT

An integrated device package is disclosed. The integrated device package can include a substrate that has a first side and a second side, an electronic component that is mounted on the first side or the second side of the substrate, a molding material that is disposed at least on the first side of the substrate, and an conductive material that is disposed on the first side of the substrate and extending through the molding material. The molding material has an exterior surface facing away from the substrate. The exterior surface of the molding material includes laser grooves indicative of laser lapping.

### CROSS-REFERENCE TO RELATED APPLICATIONS

This application claims the benefit of U.S. Provisional Application No. 63/185,143 entitled “PACKAGE WITH LASER LAPPED SURFACE AND METHOD OF MANUFACTURING SAME,” filed May 6, 2021, the entire disclosure of which is incorporated herein by reference for all purposes.

### BACKGROUND

### Field

The field relates to integrated device packages with a laser lapped surface and methods of manufacturing the same.

### Description of the Related Art

An integrated device package includes a substrate, a molding material disposed on the substrate, and an interconnect structure, such as a solder ball or a conductive pillar, exposed through the molding material. In order to achieve such a structure, complex and/or expensive processes, such as a film assist molding (FAM) process, are typically used. Accordingly, there remains a continuing need for improved integrated device packages.

### SUMMARY

For purposes of summarizing the disclosure, certain aspects, advantages, and novel features of the innovations have been described herein. It is to be understood that not necessarily all such advantages can be achieved in accordance with any particular embodiment. Thus, the innovations described herein can be embodied or carried out in a manner that achieves or optimizes one advantage or group of advantages as taught herein without necessarily achieving other advantages as can be taught or suggested herein.

In one aspect, an integrated device package is disclosed. The integrated device package can include a substrate that has a first side and a second side, an electronic component that is mounted on the first side or the second side of the substrate, a molding material that is disposed at least on the first side of the substrate, and an conductive material that is disposed on the first side of the substrate and extending through the molding material. The molding material has an exterior surface facing away from the substrate. The exterior surface of the molding material includes laser grooves indicative of laser lapping.

In one embodiment, at least a portion of the conductive material protrude above the exterior surface of the molding material.

In one embodiment, the exterior surface of the molding material includes a lower surface and a raised surface.

In one embodiment, more than 50% of the total exterior surface includes the laser grooves.

In one embodiment, the molding material includes a first portion and a second portion. The first portion is disposed on the first side of the substrate and the second portion is disposed on the second side of the substrate. The first portion can include the exterior surface. The second portion can have a second exterior surface facing away from the substrate. The second exterior surface can include laser grooves indicative of laser lapping.

In one embodiment, the conductive material includes laser grooves indicative of laser lapping.

In one embodiment, the electronic component includes an integrated device die, or a packaged device.

In one embodiment, the conductive material includes a solder ball or a metal slug.

In one embodiment, the integrated device package further includes a second conductive material disposed on the second side of the substrate.

In one aspect, an integrated device package is disclosed. The integrated device package can include a substrate that has a first side and a second side, an electronic component that is mounted on the first side, and a molding material that is disposed at least on the first side of the substrate. The molding material has an exterior surface facing away from the substrate. At least a portion of the electronic component is exposed through the molding material. The exterior surface of the molding material includes laser grooves indicative of laser lapping.

In one embodiment, at least a portion of the electronic component protrudes above the exterior surface of the molding material.

In one embodiment, the exterior surface includes a lower surface and a raised surface.

In one embodiment, more than 50% of the second surface includes the laser grooves.

In one aspect, a method of manufacturing an integrated device package is disclosed. The method can include providing a conductive material on a first side of a substrate, providing a molding material on the first side of the substrate to overmold the conductive material, and laser lapping a surface of the molding material to reveal the conductive material.

In one embodiment, the method further includes providing a second molding material on a second side of the substrate opposite the first side. The molding material and the second molding material can be provided simultaneously in a single process.

In one embodiment, the method further includes mounting an electronic component to the substrate.

In one embodiment, the laser lapping includes laser lapping more than 50% of the surface of the molding material.

In one embodiment, the laser lapping includes revealing the conductive material such that a portion of the conductive material protrudes above the surface of the molding material.

In one embodiment, the laser lapping includes removing a portion of the conductive material.

### BRIEF DESCRIPTION OF THE DRAWINGS

Specific implementations will now be described with reference to the following drawings, which are provided by way of example, and not limitation.

FIG. 1A is a schematic cross-sectional side view of an integrated device package according to an embodiment.

FIG. 1B is a close-up view of a portion of the integrated device package illustrated in FIG. 1A.

FIG. 2A is a photograph showing a surface of the integrated device package a that comprises laser grooves.

FIG. 2B is a close-up view of a portion of FIG. 2A.

FIG. 2C is a photograph showing the surface of the integrated device package after a reflow process.

FIG. 2D is a close-up view of a portion of FIG. 2C.

FIG. 3A shows a step in an example process of manufacturing the integrated device package, according to various embodiments.

FIG. 3B shows another step in the process of manufacturing the integrated device package.

FIG. 3C shows another step in the process of manufacturing the integrated device package.

FIG. 4 is a process flow chart of an example process of manufacturing the integrated device package, according to various embodiments.

FIG. 5 is a schematic cross-sectional side view of an integrated device package, according to an embodiment.

FIG. 6 is a schematic cross-sectional side view of an integrated device package, according to another embodiment.

FIG. 7 is a schematic cross-sectional side view of an integrated device package, according to another embodiment.

FIG. 8 is a schematic cross-sectional side view of an integrated device package, according to another embodiment.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals and/or terms can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Integrated device packages can include a substrate, an electronic component mounted on the substrate, and a conductive material that is configured to electrically connect an integrated device package with an external device, system, or substrate. The conductive material can comprise a solder ball, a conductive pillar, or a metal slug (e.g., a copper slug). The electronic component and the conductive material can be positioned on the same side of the substrate or on opposing sides of the substrate. A molding material can be applied to the substrate such that the electronic component and/or the conductive material is/are embedded in the molding material. When the conductive material is embedded in the molding material, at least a portion of the molding material can be removed to reveal the conductive material. The molding material can be applied to both sides of the substrate to define a double side molding structure. For example, the integrated device packages can be a package on package (POP) structure or a component on package (COP) structure.

A film assist molding (FAM) technology can be used in some packages to pre-form the shape of the molding material so as to keep a portion of the conductive material free from the molding material. However, processes using the FAM technology can be complicated. Also, FAM technology may not be suited to manufacturing a relatively large number of different types of packages, as modifications may be needed for the different types of packages.

A mechanical grinding process can be used in some packages to remove the portion of the molding material to reveal the conductive material that is at least partially embedded in the molding material. However, the mechanical grinding can damage the conductive material. For example, stress applied by the mechanical grinding to the conductive material can decouple the conductive material from the substrate.

A laser drilling process can be used to remove at least a portion of a molding material to make a hole for revealing the conductive material. However, one or more additional steps may be needed to enable the conductive material to electrically connect to the external device, system, or substrate. For example, an additional conductive material may be provided to fill the hole. The additional conductive material can increase a thickness of the integrated device package. Also, such additional steps can be time consuming and cost prohibitive. Accordingly, an improved method for manufacturing integrated device packages is desired. A laser drilled portion formed by the laser drilling process can have a laser groove. However, the additional conductive material may be disposed over and cover the laser drilled portion. Therefore, the laser drilled portion is not present on an exterior surface, in such a structure.

Various embodiments disclosed herein relate to integrated device packages with a signature of laser lapping and methods of forming the same. An integrated device package can include a substrate that has a first side and a second side. The integrated device package can include an electronic component that is mounted on the first or second side of the substrate. The integrated device package can include a molding material that is disposed at least on the first side of the substrate. The molding material has a first surface facing the first side of the substrate and a second surface (also referred to as an exterior surface) opposite the first surface. The integrated device package can include a conductive material that is disposed on the first side of the substrate and extends through the molding material. The conductive material can comprise an electrical interconnect to connect leads of the substrate (which are electrically connected to the electronic component) to an external device, such as a system board. The second exterior surface of the molding material can comprise laser grooves that are indicative of laser lapping.

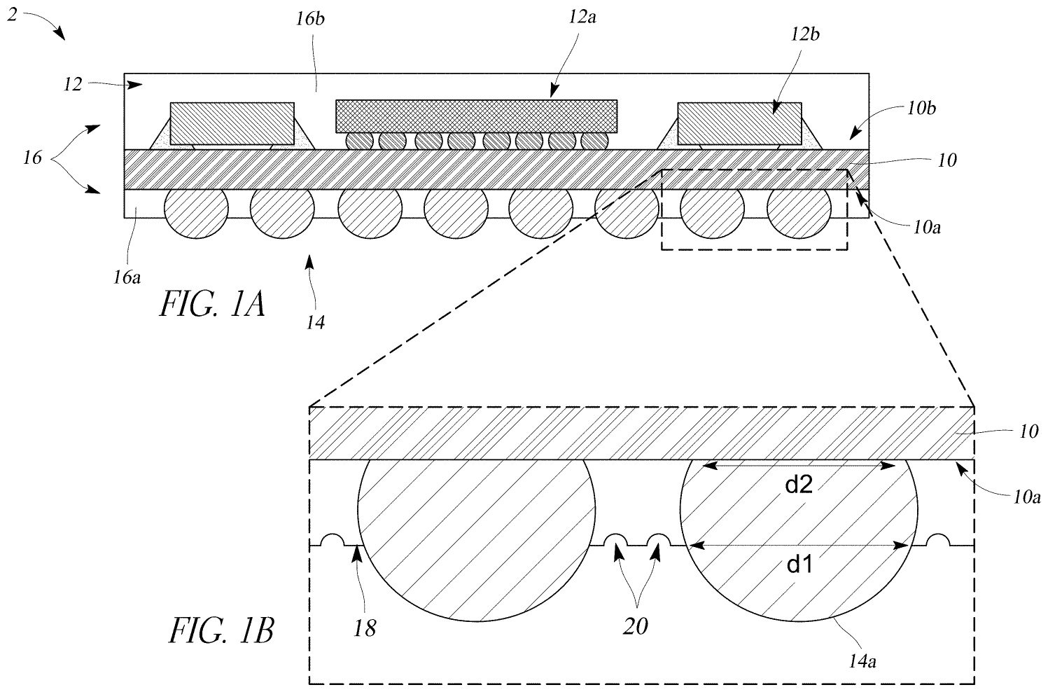

FIG. 1A is a schematic cross-sectional side view of an integrated device package 1 according to an embodiment. FIG. 1B is a close-up view of a portion of the integrated device package 1 illustrated in FIG. 1A.

The integrated device package 1 can include a substrate 10 that has a first side 10a and a second side 10b, electronic components 12 mounted on the second side 10b of the substrate 10, solder balls 14 on the first side 10a of the substrate 10, and a molding compound or material 16 that include a first portion 16a disposed on the first side 10a of the substrate 10 and a second portion 16b disposed on the second side 10b of the substrate 10. The substrate 10 can comprise any suitable substrate. In some embodiments, the substrate can comprise a laminate substrate, a ceramic substrate, a printed circuit board (PCB), a leadframe, etc.

The electronic components 12 can comprise any suitable type of components. For example, the first and second components can comprise any one of integrated device(s), integrated device die(s) (such as process dies, memory dies, microelectromechanical systems (MEMS) dies, sensor dies, optical dies, etc.), integrated circuit(s), passive electronic components (e.g., resistors, capacitors, inductors, etc.), chip components (e.g., chip passive components), a heat sink or heat slug, an integrated device package, or any other suitable type of device or component. In some embodiments, the integrated device package 1 can comprise a package on package (POP) or a component on package (COP). In some embodiments, the electronic components 12 can comprise an integrated device die 12a that is flip-chip mounted to the substrate 10, such that the die 12a is connected to the substrate 10 by way of a plurality of solder bumps. In some other embodiments, the integrated device die 12a can be wire bonded (not shown) to the substrate 10. In some embodiments, the electronic components 12 can comprise a chip component 12b that is mounted on the substrate 10 by way of a conductive adhesive.

The solder balls 14 can be configured to connect the integrated device package 1 to an external device, system, or substrate (not shown). In some embodiments, the solder balls 14 can comprise a ball grid array (e.g., a 16×16 solder ball grid array). In some embodiments, the solder balls 14 are exposed such that an exposed area of a solder ball 14a is greater than a contact area between the solder ball 14a and the substrate 10. For example, an exposed width or chord d1 of the solder ball 14a exposed through the molding material 16 can be greater than a width or chord d2 of the solder ball 14a at an interface between the solder ball 14a and the substrate 10. The greater width d1 can provide a greater contact surface as compared to the width d2 so as to achieve a more reliable connection between the substrate and the external device, system, or substrate. Laser lapping technologies disclosed herein can precisely control the amount of molding material 16 to be removed such that, for example, the width d2 is close to the maximum diameter of the solder ball 14a.

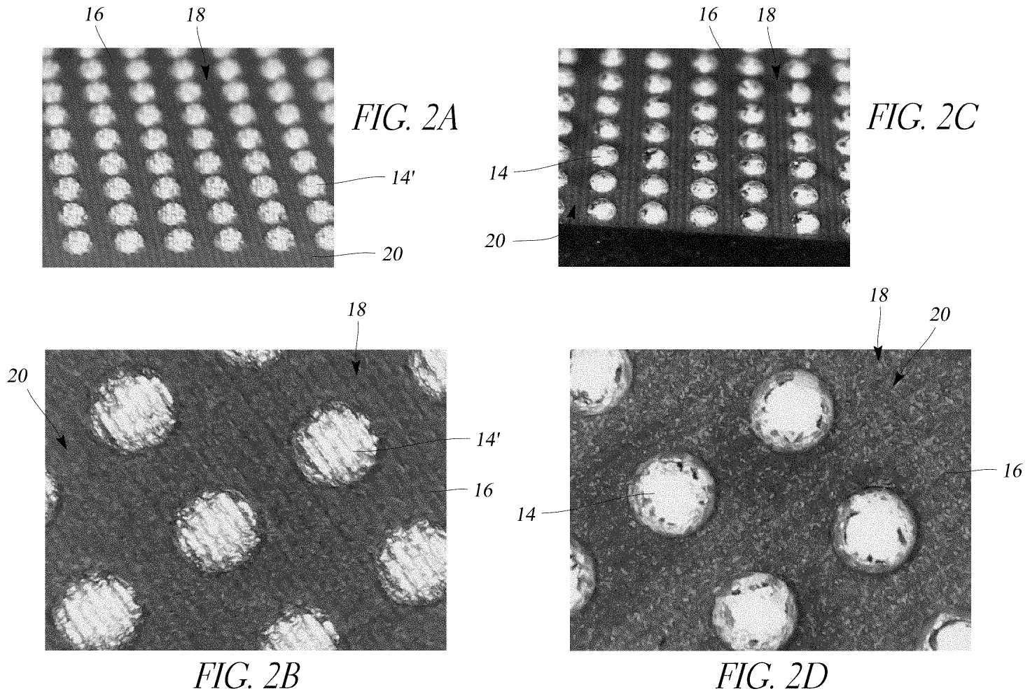

A laser grinding or lapping process can be used to remove at least a portion of the molding material 16 to reveal the solder balls 14. In the illustrated embodiment, a laser lapping process can be applied to an exterior surface 18 of the first portion 16a of the molding material 16. As shown, the exterior surface 18 can face away from the substrate 10 (and the components 12). In some embodiments, the laser lapping can use a laser marking machine. The surface 18 can have a signature of the laser lapping process. For example, the surface 18 can comprise laser grooves 20 or lines (e.g., a patterned grooves or lines) indicative of the laser lapping process. In some embodiments, the solder balls 14 may additionally have the signature of the laser lapping process (see FIGS. 2A and 2B). For example, the lapping process may be performed such that the laser interacts with both the molding material 16 and portions of the solder balls 14 such that one or both of the molding material 16 and solder balls 14 includes the signature of the laser lapping process. In some embodiments, an entirety of the exterior surface 18 can comprise the laser grooves 20. In some embodiments, a majority or more than 50% of the surface 18 can comprise the laser grooves 20.

As opposed to a conventional mechanical grinding process that applies a relatively high stress to a grinding surface for removing a portion of a molding material, less stress is applied to the exterior surface 18 when the laser lapping process is used. A relatively high stress on the grinding surface can damage internal components during the mechanical grinding process. In some embodiments, the laser lapping process can mitigate or prevent the internal components, such the solder balls 14 and/or components 12, from being damaged.

As illustrated in FIG. 1A, the integrated device package 1 can comprise a double side molding that has the first portion 16a of the molding material 16 on the first side 10a of the substrate 10 and the second portion 16b of the molding material 16 on the second side 10b of the substrate 10. In some embodiments, the double side molding can mitigate or prevent a substrate warpage. For example, a thickness of the first portion 16a and/or the second portion 16b can be about 0.7 mm or less for warpage control.

Although the laser grooves 20 are described only with respect to the first portion 16a of the molding material, a skilled artisan will understand that the second portion 16b can have an exterior surface that comprises laser grooves indicative of laser lapping. In some embodiments, an entire exposed surface of the second portion 16b of the molding material 16 can comprise the laser groove. In some embodiments, a majority of the exposed surface of the second portion 16b of the molding material 16 can comprise the laser groove.

FIG. 2A is a photograph showing a surface of the integrated device package 1 that comprises laser grooves 20. FIG. 2B is a close-up view of a portion of FIG. 2A. FIG. 2C is a photograph showing the surface of the integrated device package 1 after a reflow process. FIG. 2D is a close-up view of a portion of FIG. 2C.

As shown in FIGS. 2A-2D, the laser grooves 20 can comprise laser lines. In some embodiments, the laser grooves 20 can comprise almost equally spaced laser lines, for example, in embodiments in which laser scanning is performed along equally spaced scan lines. For example, the laser can move back-and-forth between sides of the molding material 16 to remove portions of the molding material 16 line-by-line. In some embodiments, as shown in FIGS. 2A-2D, the entirety (or substantially the entirety) of the surface 18 of the molding material 16 can comprise the laser grooves 20. In some other embodiments, a majority of the total area of the surface 18 of the molding material 16 can comprise the laser grooves 20.

As shown in FIGS. 2A and 2B, lapped solder balls 14′ can also have the laser grooves 20. In some embodiments, the lapped solder balls 14′ can protrude over the surface 18 of the molding material 16. A protrusion height of the lapped solder balls 14′ can be controlled by varying laser parameters. For example, a strength of the laser and/or a laser lapping time can be modified to control the protrusion height.

A reflow process with flux can take place over the lapped solder balls 14′ to form the solder balls 14. In some embodiments, the reflow process may be omitted and the lapped solder balls 14′ can directly be connected to an external device, system, or substrate. When the lapped solder balls 14′ are treated with the reflow process to form the solder balls 14, the solder balls 14 can protrude more relative to the surface 18 of the molding material 16 as compared to the lapped solder balls 14′. After the reflow process, the laser grooves 20 on the lapped solder balls 14′ may not be visible, in some embodiments. When the solder balls 14 are removed, the laser grooves 20 on the lapped solder balls 14′ can still be visible.

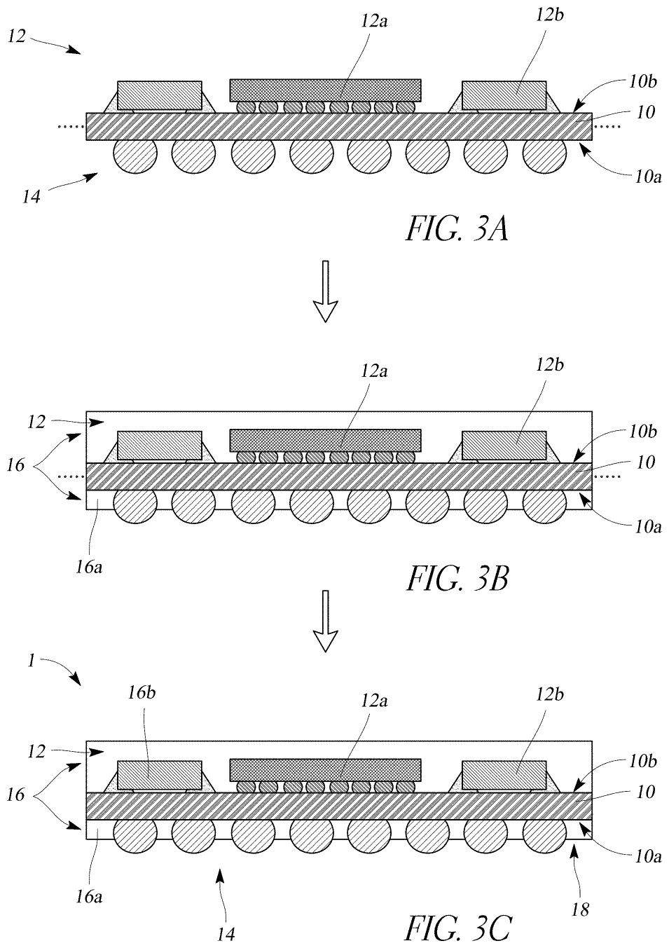

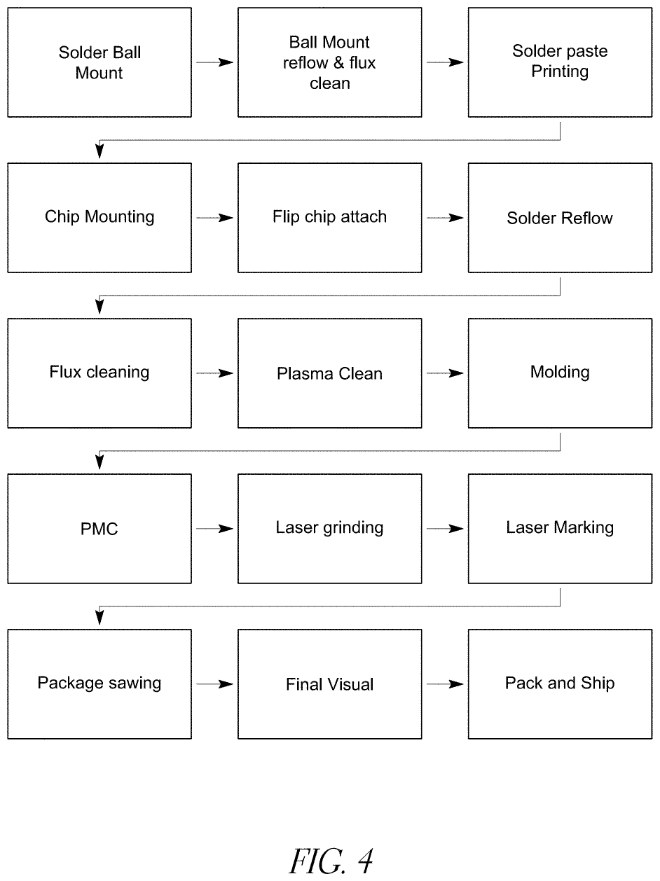

FIGS. 3A-3C show a process of manufacturing the integrated device package 1, according to an embodiment. FIG. 3A shows a step in the process of manufacturing the integrated device package 1. FIG. 3B shows another step in the process of manufacturing the integrated device package 1. FIG. 3C shows another step in the process of manufacturing the integrated device package 1. FIG. 4 is a process flow chart of the process of manufacturing the integrated device package 1.

At FIG. 3A, solder balls 14 can be mounted to a first side 10a of a substrate 10 and electronic components 12 can be mounted to a second side 10b of the substrate 10. A reflow process and/or a flux clean process can follow after the solder balls 14 are mounted. An integrated device die 12a can be flip-chip mounted to the second side 10b of the substrate 10. In FIG. 3A, the substrate 10 can extend horizontally, and more electronic components and solder balls can be provided.

At FIG. 3B, the molding material 16 can be provided. A first portion 16a of the molding material 16 can be provided on the first side 10a of the substrate 10 and a second portion 16b of the molding material 16 can be provided on the second side 10b of the substrate 10. In some embodiments, the molding material 16 can be provided by way of a one shot double side molding process. The molding material 16 can be provided such that the electronic components 12 and the solder balls 14 are at least partially embedded (e.g., fully embedded) in the molding material 16. In some embodiments, a post mold cure (PMC) process can follow after providing the molding material 16.

At FIG. 3C, at least a portion of the molding material 16 can be removed. In some embodiments, the portion of the molding material 16 can be removed by way of laser lapping to reveal the solder balls 14 through the first portion 16a of the molding material 16. A surface 18 of the first portion 16a of the molding material 16 can comprise laser grooves indicative of the laser lapping. The integrated device package 1 can be singulated by way of a singulation process. For example, the integrated device package 1 can be singulated by way of package sawing.

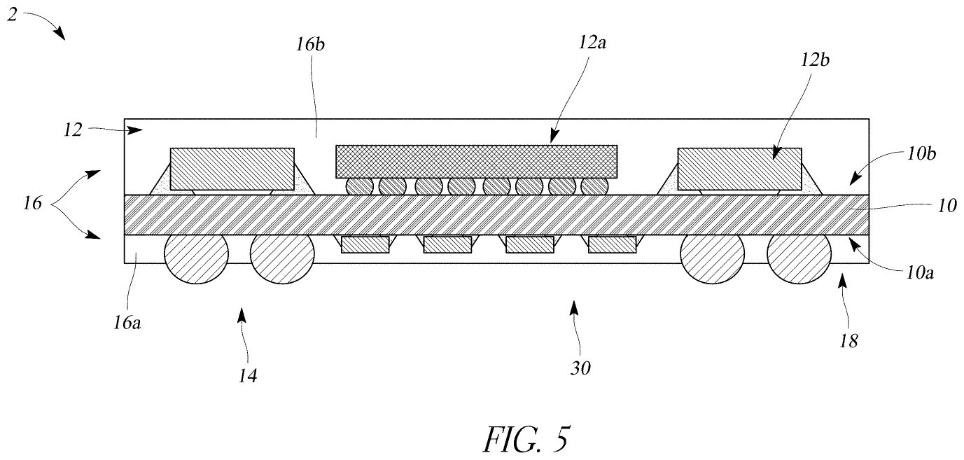

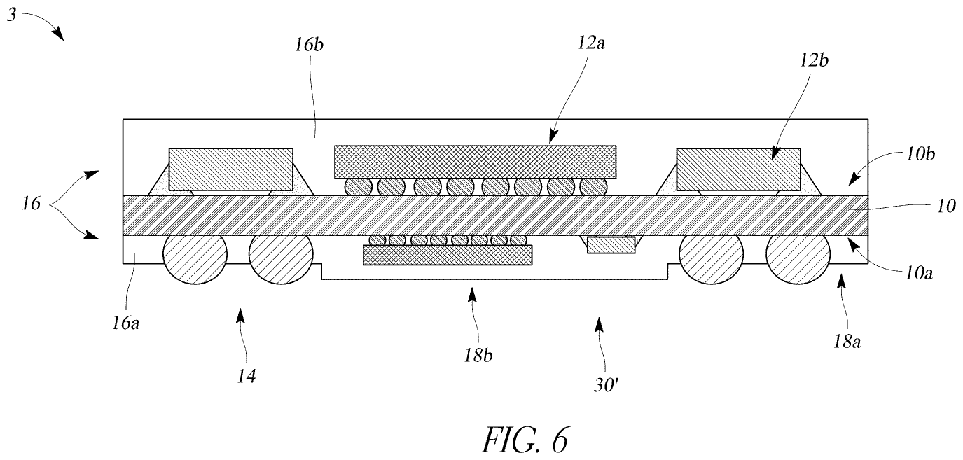

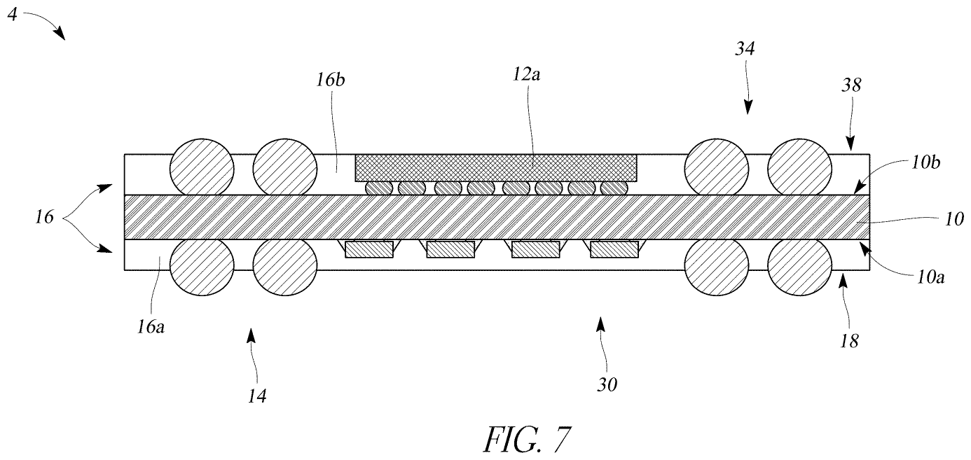

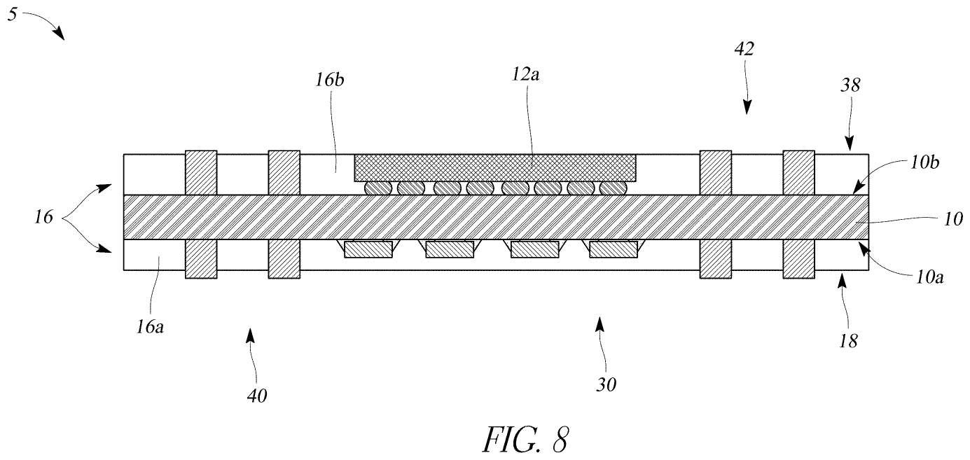

FIGS. 5-8 illustrate example integrated device packages according to various embodiments. FIG. 5 is a schematic cross-sectional side view of an integrated device package 2, according to an embodiment. FIG. 6 is a schematic cross-sectional side view of an integrated device package 3, according to another embodiment. FIG. 7 is a schematic cross-sectional side view of an integrated device package 4, according to another embodiment. FIG. 8 is a schematic cross-sectional side view of an integrated device package 5, according to another embodiment. Unless otherwise noted, components of the integrated device packages 2-5 of FIGS. 5-8 can be the same as or generally similar to like components of any integrated device package disclosed herein.

The integrated device package 2 illustrated in FIG. 5 can be generally similar to the integrated device package 1 illustrated in FIG. 1A. Unlike the integrated device package 1, the integrated device package 2 comprises electronic components 30, such as chip components, on the first side 10a of the substrate 10. Thus, in FIG. 5, electronic components can be provided on both sides 10a, 10b of the substrate 10.

The integrated device package 3 illustrated in FIG. 6 can be generally similar to the integrated device package 2 illustrated in FIG. 5. In some embodiments, the electronic components 30′ of the integrated device package 3 can comprise different types of components having different sizes. The integrated device package 3 can comprise a recessed or lower surface 18a and a raised surface 18b. In some embodiments, the electronic components 30′ can be embedded within the molding material between the first side 10a of the substrate 10 and the raised surface 18b. In some embodiments, both the recessed surface 18a and the raised surface 18b can have laser grooves indicative of laser lapping. In some embodiments, only the recessed surface 18a comprises the laser grooves indicative of laser lapping.

In the integrated device package 4 illustrated in FIG. 7, solder balls 14 are disposed on the first side 10a of the substrate 10 and solder balls 34 are disposed on the second side 10b of the substrate 10. The solder balls 14 can be exposed on a surface 18 of the first portion 16a of the molding material 16, and the solder balls 34 can be exposed on a surface 38 of the second portion 16b of the molding material 16. In some embodiments, the surfaces 18, 38 can comprise laser grooves indicative of laser lapping.

The integrated device package 5 illustrated in FIG. 8 can be generally similar to the integrated device package 4 illustrated in FIG. 7. In the integrated device package 5 metal slugs 40, 42 can be used in place of the solder balls 14, 34 of the integrated device package 4. In some embodiments, the metal slugs 40, 42 can comprise copper lugs. The sluts 40, 42 can be picked and placed on the substrate 10 in various embodiments, for example, by way of a conductive adhesive and/or by a thermocompression bonding technique.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

The foregoing description has been described with reference to specific embodiments. However, the illustrative discussions above are not intended to be exhaustive or to limit the inventions to the precise forms described. Many modifications and variations are possible in view of the above teachings. Others skilled in the art are thereby enabled to best utilize the techniques and various embodiments with various modifications as suited to various uses.

Although the disclosure and examples have been described with reference to the accompanying drawings, various changes and modifications will become apparent to those skilled in the art. Such changes and modifications are to be understood as being included within the scope of the disclosure.

What is claimed is:

1. An integrated device package comprising:
a substrate having a first side and a second side;
an electronic component mounted on the first side or the second side of the substrate;
a molding material disposed at least on the first side of the substrate, the molding material having an exterior surface facing away from the substrate; and
an conductive material disposed on the first side of the substrate and extending through the molding material,
wherein the exterior surface of the molding material comprises laser grooves indicative of laser lapping.

2. The integrated device package of claim 1, wherein at least a portion of the conductive material protrude above the exterior surface of the molding material.

3. The integrated device package of claim 1, wherein the exterior surface of the molding material comprises a lower surface and a raised surface.

4. The integrated device package of claim 1, wherein more than 50% of the total exterior surface comprises the laser grooves.

5. The integrated device package of claim 1, wherein the molding material comprises a first portion and a second portion, the first portion is disposed on the first side of the substrate and the second portion is disposed on the second side of the substrate, the first portion including the exterior surface, and the second portion having a second exterior surface facing away from the substrate.

6. The integrated device package of claim 5, wherein the second exterior surface comprises laser grooves indicative of laser lapping.

7. The integrated device package of claim 1, wherein the conductive material comprises laser grooves indicative of laser lapping.

8. The integrated device package of claim 1, wherein the electronic component comprises an integrated device die, or a packaged device.

9. The integrated device package of claim 1, wherein the conductive material comprises a solder ball or a metal slug.

10. The integrated device package of claim 1, further comprising a second conductive material disposed on the second side of the substrate.

11. An integrated device package comprising:
a substrate having a first side and a second side;
an electronic component mounted on the first side; and
a molding material disposed at least on the first side of the substrate, the molding material having an exterior surface facing away from the substrate,
wherein at least a portion of the electronic component is exposed through the molding material, and the exterior surface of the molding material comprises laser grooves indicative of laser lapping.

12. The integrated device package of claim 11, wherein at least a portion of the electronic component protrudes above the exterior surface of the molding material.

13. The integrated device package of claim 11, wherein the exterior surface comprises a lower surface and a raised surface.

14. The integrated device package of claim 11, wherein more than 50% of the second surface comprises the laser grooves.

15. A method of manufacturing an integrated device package, the method comprising:
providing a conductive material on a first side of a substrate;
providing a molding material on the first side of the substrate to overmold the conductive material; and
laser lapping a surface of the molding material to reveal the conductive material.

16. The method of claim 15, further comprising providing a second molding material on a second side of the substrate opposite the first side.

17. The method of claim 16, wherein the molding material and the second molding material are provided simultaneously in a single process.

18. The method of claim 15, further comprising mounting an electronic component to the substrate.

19. The method of claim 15, wherein the laser lapping comprises laser lapping more than 50% of the surface of the molding material.

20. The method of claim 15, wherein the laser lapping comprises revealing the conductive material such that a portion of the conductive material protrudes above the surface of the molding material, the laser lapping comprises removing a portion of the conductive material.
